(19) United States
(12) Patent Application Publication
(10) Pub. No.: US 2025/0224443 A1
(43) Pub. Date: Jul. 10, 2025

(54) Dynamic Voltage Stress Condition Optimization Method and Dynamic Voltage Stress Condition Optimization System Capable of Performing Block-based Dynamic Voltage Stress Wafer Testing Process

(71) Applicant: MEDIATEK INC., Hsinchu City (TW)

(72) Inventors: Yu-Lin Yang, Hsinchu City (TW); Po-Chao Tsao, Hsinchu City (TW); Yun-San Huang, Hsinchu City (TW); Chia-Chun Sun, Hsinchu City (TW); Chin-Wei Lin, Hsinchu City (TW); Ming-Cheng Lee, Hsinchu City (TW); Tung-Hsing Lee, Hsinchu City (TW); Wei-Lien Chen, Hsinchu City (TW)

(73) Assignee: MEDIATEK INC., Hsinchu City (TW)

(21) Appl. No.: 19/048,861

(22) Filed: Feb. 8, 2025

Related U.S. Application Data
(63) Continuation-in-part of application No. 18/407,466, filed on Jan. 9, 2024.

(51) Int. Cl. G01R 31/28

(52) U.S. Cl. CPC G01R 31/2879; G01R 31/2868; G01R 31/2875

(57) ABSTRACT

A dynamic voltage stress (DVS) condition optimization includes selecting a testing block from a plurality of blocks in a die of a wafer, acquiring a plurality of testing block measurement temperatures of the testing block when the testing block is processed by a DVS testing flow, acquiring a correlation table of the plurality of testing block measurement temperatures and a plurality of DVS block predict temperatures of the testing block, configuring a tip burnt block temperature based on the testing block measurement temperatures, determining a DVS block target temperature selected from the DVS block predict temperatures based on the correlation table and the tip burnt block temperature, and generating a DVS block voltage for applying to the testing block in the die of the wafer based on the DVS block target temperature.

### CROSS REFERENCE TO RELATED APPLICATION

This application is a continuation-in-part of U.S. application Ser. No. 18/407,466, filed on Jan. 9, 2024. The content of the application is incorporated herein by reference.

### BACKGROUND

With the rapid development of technologies, improving wafer yield is an important issue in wafer fabrication in the industry. To improve the reliability of wafer fabrication, reducing dynamic voltage stress (DVS) failure rate and defects per million (DPPM) is a major goal. Specifically, a DVS test can be applied to sense process variations of critical layers, points, or weak layout patterns of a testing product. For wafer defect-based testing processes, when DVS conditions are optimized, the DPPM can be reduced.

However, in current DVS tests, a fixed DVS voltage is applied to all blocks of a die. As a result, the current DVS test is not optimized. Therefore, developing a DVS condition optimization method for improving the wafer defect-based testing process is important.

### SUMMARY

In an embodiment, a dynamic voltage stress (DVS) condition optimization method is disclosed. The DVS condition optimization method comprises selecting a testing block from a plurality of testing blocks in a die of a wafer, acquiring a plurality of testing block measurement temperatures of the testing block when the testing block is processed by a DVS testing flow, acquiring a correlation table of the plurality of testing block measurement temperatures and a plurality of DVS block predict temperatures of the testing block, configuring a tip burnt block temperature based on the plurality of testing block measurement temperatures, determining a DVS block target temperature selected from the DVS block predict temperatures based on the correlation table and the tip burnt block temperature, and generating a DVS block voltage for applying to the testing block in the die of the wafer based on the DVS block target temperature.

In another embodiment, a DVS condition optimization system is disclosed. The DVS condition optimization system comprises at least one wafer testing station, a memory, and a processor coupled to the memory and the at least one wafer testing station. The processor selects a testing block from a plurality of testing blocks in a die of a wafer. The processor acquires a plurality of testing block measurement temperatures of the testing block from the at least one wafer testing station when the testing block is processed by a DVS testing flow. The processor acquires a correlation table of the plurality of testing block measurement temperatures and a plurality of DVS block predict temperatures of the testing block. The correlation table is saved in the memory. The processor configures a tip burnt block temperature based on the testing block measurement temperatures. The processor determines a DVS block target temperature selected from the DVS block predict temperatures based on the correlation table and the tip burnt block temperature. The processor generates a DVS block voltage for applying to the testing block in the die of the wafer based on the DVS block target temperature.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a dynamic voltage stress condition optimization system based on a first embodiment of the present invention.

FIG. 2 is an illustration of a first data flow mode of the dynamic voltage stress condition optimization system in FIG. 1.

FIG. 3 is an illustration of a second data flow mode of the dynamic voltage stress condition optimization system in FIG. 1.

FIG. 4 is an illustration of a third data flow mode of the dynamic voltage stress condition optimization system in FIG. 1.

FIG. 5 is an illustration of a correlation table applied to data flow modes in FIG. 2 to FIG. 4 of the dynamic voltage stress condition optimization system in FIG. 1.

FIG. 6 is an illustration of applying different DVS block voltages to different testing blocks in a die of a wafer by using the dynamic voltage stress condition optimization system in FIG. 1.

FIG. 7 is an illustration of setting different tip burnt boundary bands to different testing blocks by using the dynamic voltage stress condition optimization system in FIG. 1.

FIG. 8 is a flow chart of performing a dynamic voltage stress condition optimization method by the dynamic voltage stress condition optimization system in FIG. 1.

FIG. 9 is an illustration of a fourth data flow mode of the dynamic voltage stress condition optimization system in FIG. 1.

FIG. 10 is an illustration of a fifth data flow mode of the dynamic voltage stress condition optimization system in FIG. 1.

FIG. 11 is an illustration of a sixth data flow mode of the dynamic voltage stress condition optimization system in FIG. 1.

FIG. 12 is an illustration of a correlation table applied to data flow modes in FIG. 9 to FIG. 11 of the dynamic voltage stress condition optimization system in FIG. 1.

### DETAILED DESCRIPTION

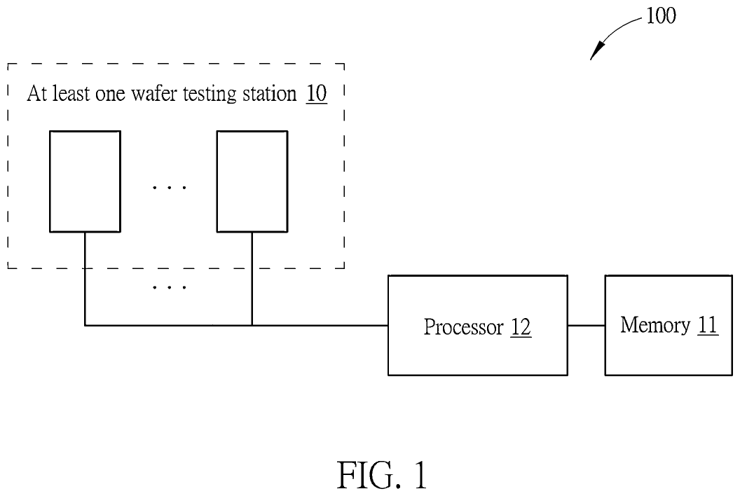

FIG. 1 is a block diagram of a dynamic voltage stress (DVS) condition optimization system 100 based on a first embodiment of the present invention. The DVS condition optimization system 100 includes at least one wafer testing station 10, a memory 11, and a processor 12. The at least one wafer testing station 10 is used for processing a wafer testing flow. The memory 11 is used for saving data, such as parameters of a machine learning model and/or a correlation table. The processor 12 is coupled to the memory 11 and the at least one wafer testing station 10 and is used for determining an appropriate DVS block voltage. In the DVS condition optimization system 100, the processor 12 selects a testing block from a plurality of testing blocks in a die of a wafer. For example, the processor 12 can select a central processing unit (CPU) block as the testing block. Particularly, the CPU block requires high power consumption. Therefore, the CPU block has the worst temperature tolerance compared with other blocks. After the testing block is selected, the processor 12 acquires a plurality of testing block measurement temperatures of the testing block from the at least one wafer testing station 10 when the testing block is processed by a DVS testing flow. Here, the “testing block measurement temperatures” can be regarded as real temperatures measured from the at least one wafer testing station 10. Then, the processor 12 acquires the correlation table of the plurality of testing block measurement temperatures and a plurality of DVS block predict temperatures of the testing block. The correlation table is saved in the memory 11. The processor 12 determines a tip burnt block temperature based on the testing block measurement temperatures. The tip burnt block temperature can be regarded as a maximum tolerance temperature of the testing block under the DVS testing flow. Then, the processor 12 determines a DVS block target temperature selected from the DVS block predict temperatures based on the correlation table and the tip burnt block temperature. Finally, the processor 12 generates a DVS block voltage for applying to the testing block in the die of the wafer based on the DVS block target temperature. In the DVS condition optimization system 100, the processor 12 can adjust the DVS block voltage for applying to another testing block in the die of the wafer. In other words, the die of the wafer includes a plurality of testing blocks. The plurality of testing blocks can be applied with different DVS block voltages. Details of optimizing the DVS conditions for adaptively applying to different testing blocks are illustrated below.

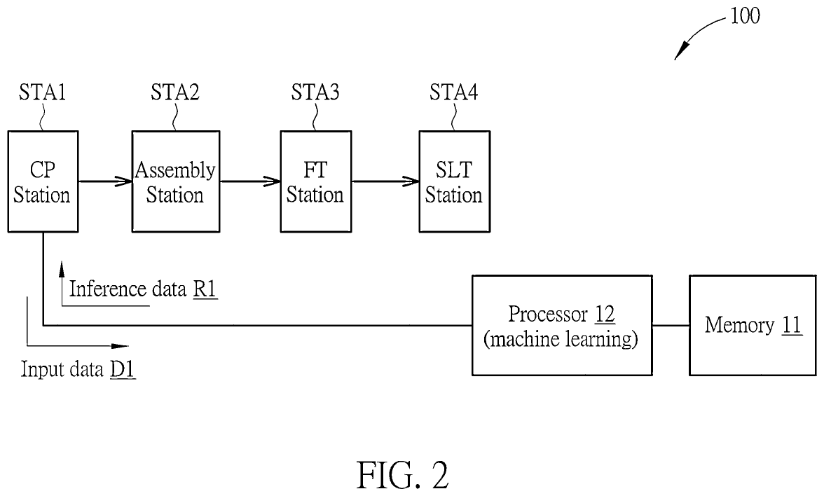

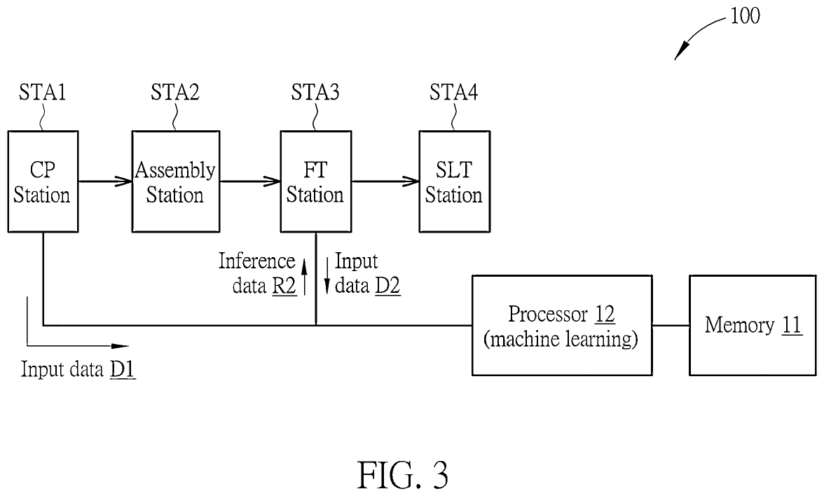

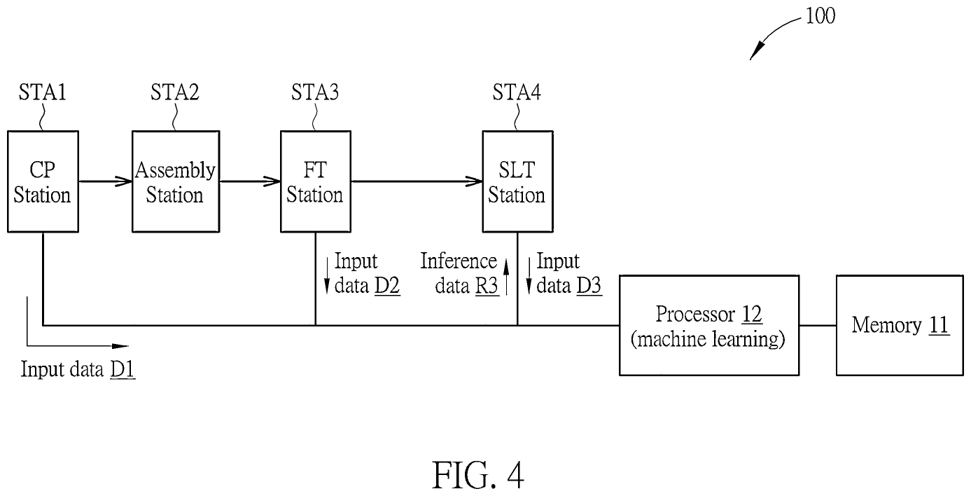

FIG. 2 is an illustration of a first data flow mode of the DVS condition optimization system 100. FIG. 3 is an illustration of a second data flow mode of the DVS condition optimization system 100. FIG. 4 is an illustration of a third data flow mode of the DVS condition optimization system 100. As mentioned previously, the at least one wafer testing station 10 is used for processing a wafer testing flow. For example, in FIG. 2 to FIG. 4, a chip probe (CP) stage, an assembly stage, a final test (FT) stage, and a system-level testing (SLT) stage are introduced. The CP stage is performed by a CP station STA1. The assembly stage is performed by an assembly station STA2. The FT stage is performed by an FT station STA3. The SLT stage is performed by an SLT station STA4. In the DVS condition optimization system 100, the processor 12 can acquire pre-DVS data of the wafer before the wafer is processed by the DVS testing flow. Then, the processor 12 can generate the plurality of DVS block predict temperatures of the testing block to establish the correlation table by a machine learning architecture based on the pre-DVS data. For example, in FIG. 2, the pre-DVS data is acquired from the CP stage performed by the CP station STA1. Therefore, the pre-DVS data of the CP stage can be regarded as input data D1 of the machine learning architecture. Furthermore, the processor 12 can acquire testing block measurement temperatures from the CP station STA1. Therefore, the machine learning architecture can be trained by the input data D1 for generating a machine learning model. The machine learning model is used for generating the DVS block predict temperatures. Therefore, the correlation table of the plurality of testing block measurement temperatures and a plurality of DVS block predict temperatures can be determined. Finally, a DVS block voltage can be outputted as inference data R1 from the processor 12 to the CP station STA1 for applying to the testing block in the die of the wafer. In FIG. 2, the wafer is processed by the DVS testing flow in the CP stage.

In FIG. 3, the pre-DVS data can be acquired from the CP stage performed by the CP station STA1 and the FT stage performed by the FT station STA3. Therefore, the pre-DVS data of the CP stage can be regarded as input data D1 of the machine learning architecture. The pre-DVS data of the FT stage can be regarded as input data D2 of the machine learning architecture. Further, the processor 12 can acquire testing block measurement temperatures from the FT station STA3. Therefore, the machine learning architecture can be trained by the input data D1 and the input data D2 for generating a machine learning model. The machine learning model can be used for generating the DVS block predict temperatures. Therefore, the correlation table of the testing block measurement temperatures and DVS block predict temperatures can be determined. Finally, the processor 12 can output a DVS block voltage as inference data R2 to the FT station STA3 for applying to the testing block in the die of the wafer. In FIG. 3, the wafer is processed by the DVS testing flow in the FT stage.

In FIG. 4, the pre-DVS data can be acquired from the CP stage performed by the CP station STA1, the FT stage performed by the FT station STA3, and the SLT stage performed by the SLT station STA4. Therefore, the pre-DVS data of the CP stage can be regarded as input data D1 of the machine learning architecture. The pre-DVS data of the FT stage can be regarded as input data D2 of the machine learning architecture. The pre-DVS data of the SLT stage can be regarded as input data D3 of the machine learning architecture. Further, the processor 12 can acquire testing block measurement temperatures from the SLT station STA4. Therefore, the machine learning architecture can be trained by input data D1, input data D2, and input data D3 for generating a machine learning model. The machine learning model can be used for generating the DVS block predict temperatures. Therefore, the correlation table of the testing block measurement temperatures and the DVS block predict temperatures can be determined. Finally, the processor 12 can output a DVS block voltage as inference data R3 to the SLT station STA4 for applying to the testing block in the die of the wafer. In FIG. 4, the wafer is processed by the DVS testing flow in the SLT stage.

In the DVS condition optimization system 100, the correlation table can be generated by using the machine learning model by the processor 12. In other embodiments, the correlation table can be acquired by any reasonable method. Any reasonable technology or hardware modification falls into the scope of the embodiments.

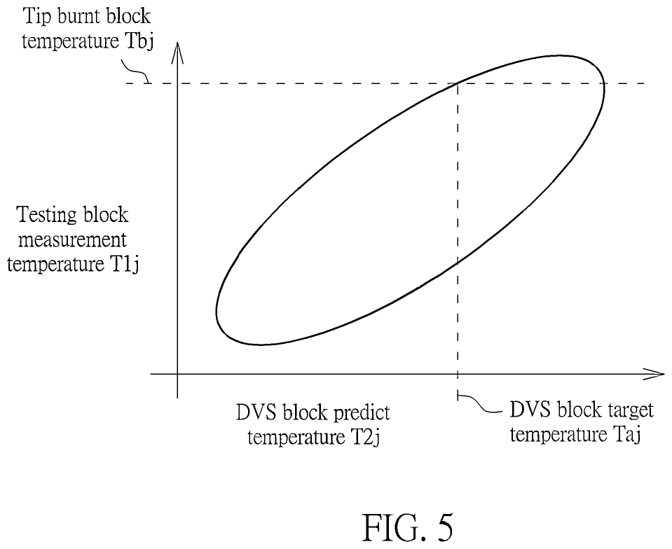

FIG. 5 is an illustration of the correlation table applied to data flow modes in FIG. 2 to FIG. 4 of the DVS condition optimization system 100. In FIG. 5, the Y-axis shows the testing block measurement temperature of the j-th testing block, denoted as T1j. The X-axis shows the DVS block predicted temperature of the j-th testing block, denoted as T2j. The tip burnt block temperature of the j-th testing block is denoted as Tbj. The tip burnt block temperature Tbj can be regarded as the maximum tolerance temperature of the j-th testing block under the DVS testing flow. Based on the tip burnt block temperature Tbj and the correlation table, the DVS block target temperature of the j-th testing block can be determined, denoted as Taj. In other words, when the DVS block voltage corresponding to the DVS block target temperature Taj is applied to the j-th testing block used for performing the DVS testing flow, the testing block measurement temperature of the j-th testing block approaches the tip burnt block temperature Tbj. In other words, when the processor 12 increases the DVS block voltage for approaching the testing block measurement temperature to the tip burnt block temperature Tbj, the DVS block voltage applied to the j-th testing block is increased, leading to a defect parts per million (DPPM) reduction.

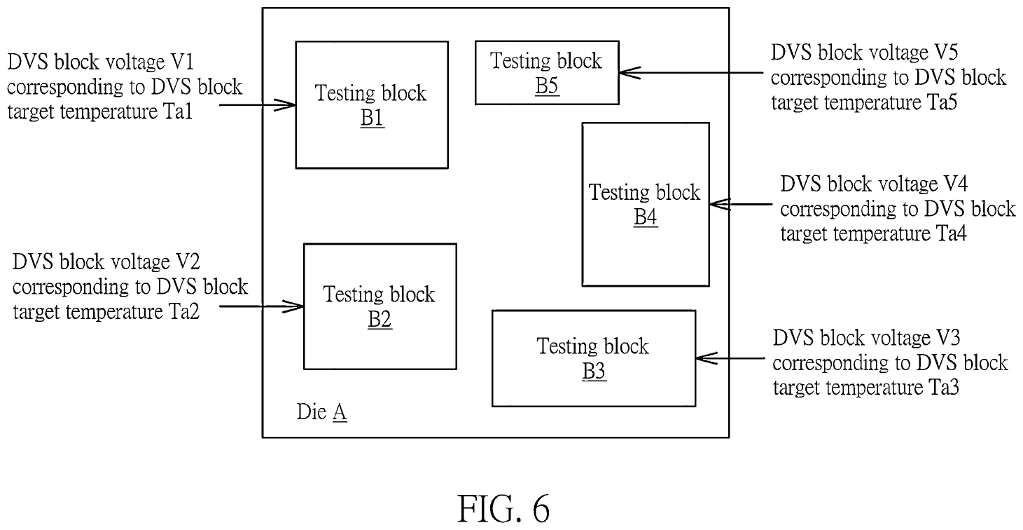

FIG. 6 is an illustration of applying different DVS block voltages to different testing blocks in the die A of the wafer by using the DVS condition optimization system 100. As previously mentioned, the die A of the wafer includes the plurality of testing blocks. The plurality of testing blocks can be applied with different DVS block voltages. For example, in FIG. 6, the die A includes a testing block B1, a testing block B2, a testing block B3, a testing block B4, and a testing block B5 (i.e., j=5). The DVS block voltage V1 corresponding to a DVS block target temperature Ta1 is applied to the testing block B1. The DVS block voltage V2 corresponding to a DVS block target temperature Ta2 is applied to the testing block B2. The DVS block voltage V3 corresponding to a DVS block target temperature Ta3 is applied to the testing block B3. The DVS block voltage V4 corresponding to a DVS block target temperature Ta4 is applied to the testing block B4. The DVS block voltage V5 corresponding to a DVS block target temperature Ta5 is applied to the testing block B5. Since the DVS block voltages can be adaptively applied to corresponding testing blocks, the efficiency and the accuracy of the DVS testing flow can be improved.

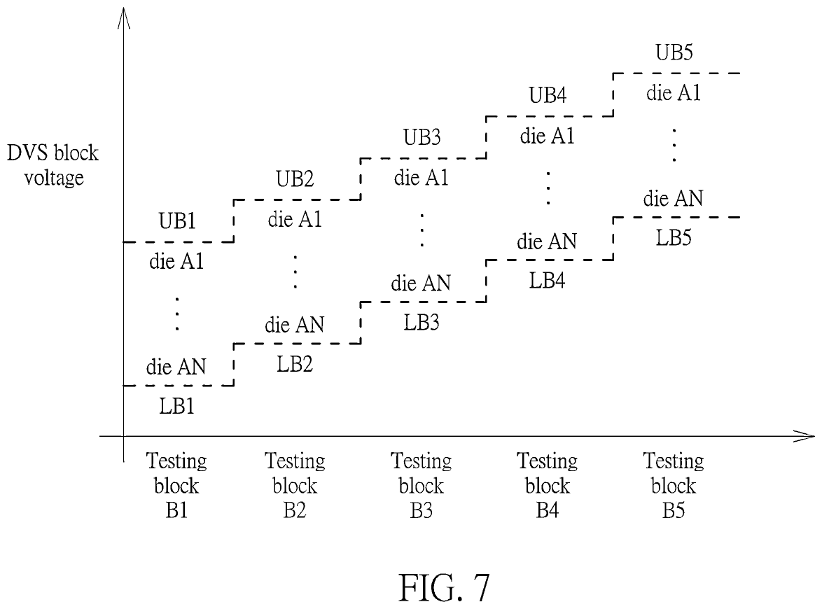

FIG. 7 is an illustration of setting different tip burnt boundary bands to different testing blocks by using the DVS condition optimization system 100. In the DVS condition optimization system 100, the plurality of testing blocks can be applied with different DVS block voltages. Further, the wafer includes a plurality of dies. DVS characteristics of the plurality of dies are different due to manufacturing differences. Therefore, a tip burnt boundary band can be determined based on the DVS characteristics of the plurality of dies. For example, in FIG. 7, for the testing block B1, a tip burnt boundary band of a die A1 to a die AN is between an upper bound DVS block voltage UB1 and a lower bound DVS block voltage LB1. For the testing block B2, a tip burnt boundary band of the die A1 to the die AN is between an upper bound DVS block voltage UB2 and a lower bound DVS block voltage LB2. For the testing block B3, a tip burnt boundary band of the die A1 to the die AN is between an upper bound DVS block voltage UB3 and a lower bound DVS block voltage LB3. For the testing block B4, a tip burnt boundary band of the die A1 to the die AN is between an upper bound DVS block voltage UB4 and a lower bound DVS block voltage LB4. For the testing block B5, a tip burnt boundary band of the die A1 to the die AN is between an upper bound DVS block voltage UB5 and a lower bound DVS block voltage LB5. In other words, for N dies, when the tip burnt boundary band is determined based on the upper bound DVS block voltage and the lower bound DVS block voltage by the processor 12, the DVS block voltage applied to the testing block is between the upper bound DVS block voltage and the lower bound DVS block voltage.

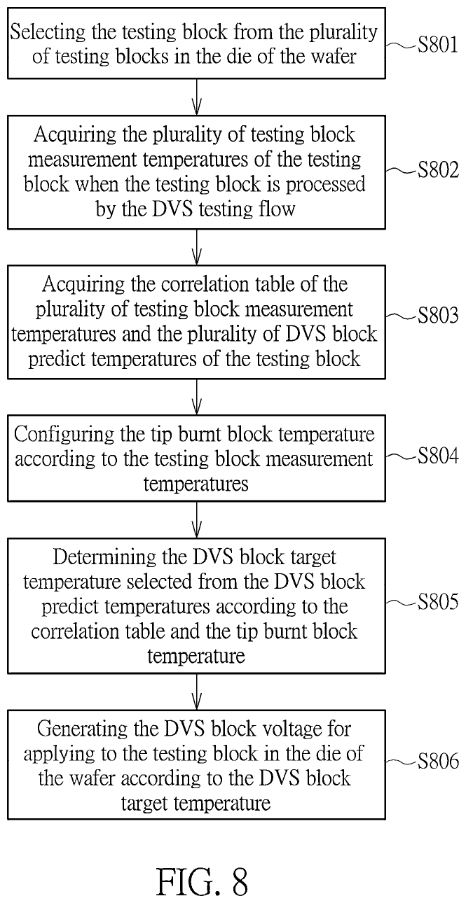

FIG. 8 is a flow chart of performing a DVS condition optimization method by the DVS condition optimization system 100. The DVS condition optimization method includes step S801 to step S806. Any reasonable technology modification falls into the scope of the embodiments. Step S801 to step S806 are illustrated below.
Step S801: selecting the testing block from the plurality of testing blocks in the die of the wafer;
Step S802: acquiring the plurality of testing block measurement temperatures of the testing block when the testing block is processed by the DVS testing flow;
Step S803: acquiring the correlation table of the plurality of testing block measurement temperatures and the plurality of DVS block predict temperatures of the testing block;
Step S804: configuring the tip burnt block temperature based on the testing block measurement temperatures;
Step S805: determining the DVS block target temperature selected from the DVS block predict temperatures based on the correlation table and the tip burnt block temperature;
Step S806: generating the DVS block voltage for applying to the testing block in the die of the wafer based on the DVS block target temperature.

Details of step S801 to step S806 are previously illustrated. Thus, they are omitted here. In the DVS condition optimization system 100, the DVS block voltage can be generated based on the DVS block target temperature. Therefore, when the testing block is processed by the DVS testing flow, the testing block measurement temperature can approach the tip burnt block temperature. As a result, the DVS block voltage of the DVS testing flow can be optimized.

Further, the dynamic voltage stress condition optimization system 100 can use both pre-DVS data and expected DVS stress time (i.e., hereafter referred to as DVS time duration) to predict post-DVS temperature. The DVS time duration, which refers to the length of applying the stressed voltage, is a crucial factor in accurately predicting the post-DVS temperature of the IC. This is primarily because heat from the DVS process accumulates within the IC over time. The longer the DVS time duration, the more heat accumulates within the IC. This accumulation can significantly impact the accuracy of post-DVS temperature predictions. The processor 12 can better predict the thermal behavior of the IC under stress and make more informed decisions regarding the DVS process, by incorporating DVS time duration into the prediction model. Furthermore, incorporating DVS time duration into the prediction model allows for greater accuracy in determining the appropriate DVS conditions, which, in turn, helps prevent overheating, a major cause of IC failure. Manufacturers can improve the reliability and lifespan of their products by optimizing the DVS process. In the following, some embodiments of using both pre-DVS data and DVS time duration to perform the dynamic voltage stress condition optimization method are illustrated.

For the architecture in FIG. 2, as previously mentioned, the CP stage is performed by a CP station STA1. The assembly stage is performed by an assembly station STA2. The FT stage is performed by an FT station STA3. The SLT stage is performed by an SLT station STA4. The pre-DVS data can be acquired from the CP stage performed by the CP station STA1. The processor can set a plurality of DVS block voltages and a plurality of DVS time durations applied to the CP stage. The pre-DVS data of the CP stage can be regarded as the input data D1 of the machine learning architecture. The pre-DVS data of the CP stage can include the die's environment temperature in the CP stage. Then, the processor 12 can generate (i.e., infer) the plurality of DVS block predict temperatures of the testing block to establish a correlation table by a machine learning architecture based on the pre-DVS data, the plurality of DVS block voltages, and the plurality of DVS time durations for the CP stage. The machine-learning model can be used for generating the DVS block predict temperatures under various DVS block voltages and various DVS time durations for the CP stage. For example, the processor 12 can predict that the DVS block predict temperature of the CP stage is equal to 60 degrees Celsius after the DVS block voltage (1.6 volts) tests the die block for 20 seconds. After generating the DVS block predict temperatures under various DVS block voltages and various DVS time durations, an optimal DVS block voltage for a corresponding DVS time duration can be determined and outputted as inference data R1 from the processor 12 to the CP station STA1 for applying to the wafer testing flow in the die of the wafer.

For the architecture in FIG. 3, the pre-DVS data can be acquired from the CP stage performed by the CP station STA1 and the FT stage performed by the FT station STA3. The pre-DVS data of the CP stage can be regarded as the input data D1 of the machine learning architecture. The pre-DVS data of the FT stage can be regarded as the input data D2 of the machine-learning architecture. The pre-DVS data of the CP stage (input data D1) can include the die's environment temperature in the CP stage. The pre-DVS data of the FT stage (the input data D2) can include the die's environment temperature in the FT stage. Then, the processor 12 can generate (i.e., infer) the plurality of DVS block predict temperatures of the testing block to establish a correlation table by the machine-learning architecture based on the pre-DVS data (input data D1 and D2), the plurality of DVS block voltages, and the plurality of DVS time durations for the FT stage. For example, the processor 12 can predict that the DVS block predict temperature of the FT stage is equal to 50 degrees Celsius after the DVS block voltage (1.5 volts) tests the die block for 20 seconds. After generating the DVS block predict temperatures under various DVS block voltages and various DVS time durations, an optimal DVS block voltage for a corresponding DVS time duration can be determined and outputted as inference data R2 from the processor 12 to the FT station STA3 for applying to the wafer testing flow in the die of the wafer.

For the architecture in FIG. 4, the pre-DVS data can be acquired from the CP stage performed by the CP station STA1, the FT stage performed by the FT station STA3, and the STL stage performed by the SLT station STA4. The pre-DVS data of the CP stage can be regarded as the input data D1 of the machine learning architecture. The pre-DVS data of the FT stage can be regarded as the input data D2 of the machine learning architecture. The pre-DVS data of the SLT stage can be regarded as the input data D3 of the machine learning architecture. The pre-DVS data of the CP stage (input data D1) can include the environment temperature of the die in the CP stage. The pre-DVS data of the FT stage (the input data D2) can include the environment temperature of the die in the FT stage. The pre-DVS data of the SLT stage (the input data D3) can include the environment temperature of the die in the SLT stage. Then, the processor 12 can generate (i.e., infer) the plurality of DVS block predict temperatures of the testing block to establish a correlation table by the machine learning architecture based on the pre-DVS data (input data D1 to D3), the plurality of DVS block voltages, and the plurality of DVS time durations for the SLT stage. For example, the processor 12 can predict that the DVS block predict temperature of the SLT stage is equal to 40 degrees Celsius after the DVS block voltage (1.6 volts) tests the die block for one second. After generating the DVS block predict temperatures under various DVS block voltages and various DVS time durations, an optimal DVS block voltage for a corresponding DVS time duration can be determined and outputted as inference data R3 from the processor 12 to the SLT station STA4 for applying to the wafer testing flow in the die of the wafer.

To ensure the quality of manufacturing ICs, the ICs are tested under three different temperature conditions during various manufacturing stages. In other words, ICs need to operate reliably across a range of temperatures. By testing at different temperatures (i.e., low temperature, normal temperature, and high temperature), manufacturers can identify potential issues that might only occur under specific thermal conditions. This three-temperature testing process helps filter out defective chips and ensure that only those meeting the required quality standards are shipped. In general, Low Temperature (LT) testing is conducted at temperatures typically below −25 degrees Celsius. LT testing can identify defective IC issues that might occur in extremely cold environments. Normal Temperature (NT) testing is performed at room temperature, typically around 25 degrees Celsius (25-30 degrees Celsius). This testing assesses the IC's performance under typical operating conditions. High Temperature (HT) testing is conducted at temperatures ranging from 80 to 125 degrees Celsius. HT testing can identify defective IC issues that might occur in extremely hot environments. In the following embodiments, details of operating the dynamic voltage stress condition optimization system 100 under the three-temperature testing process for various stages are illustrated.

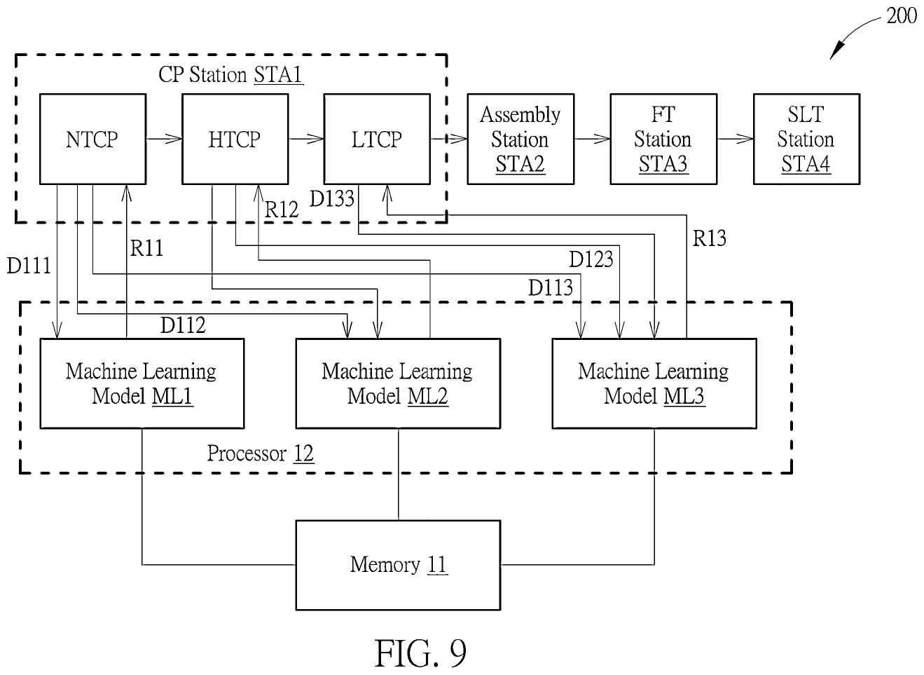

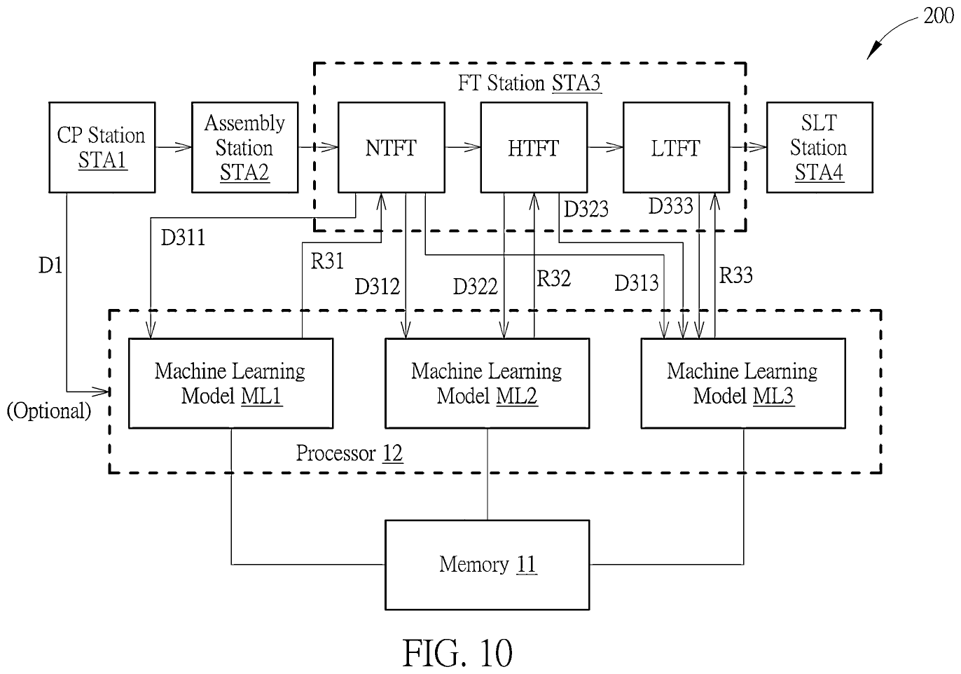

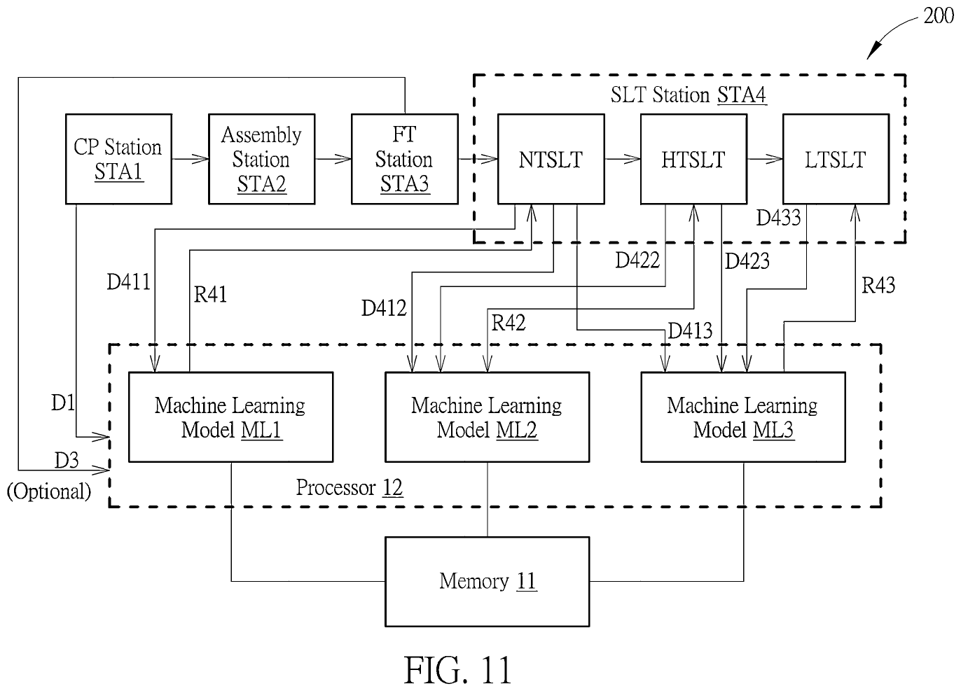

FIG. 9 is an illustration of a fourth data flow mode of the dynamic voltage stress condition optimization system 100. FIG. 10 is an illustration of a fifth data flow mode of the dynamic voltage stress condition optimization system 100. FIG. 11 is an illustration of a sixth data flow mode of the dynamic voltage stress condition optimization system 100. To avoid ambiguity, the dynamic voltage stress condition optimization system 100 in FIG. 9 to FIG. 11 is referred to as the dynamic voltage stress condition optimization system 200 hereafter. In FIG. 9, the pre-DVS data is acquired from the CP stage performed by the CP station STA1 within the wafer testing flow. This CP stage is further divided into three sub-stages: a normal temperature CP testing sub-stage NTCP, a high temperature CP testing sub-stage HTCP, and a low temperature CP testing sub-stage LTCP. The wafer undergoes a wafer thermal cycling CP testing process as part of the DVS testing flow during the CP stage. The normal temperature CP testing sub-stage NTCP, the high temperature CP testing sub-stage HTCP, and the low temperature CP testing sub-stage LTCP are processed sequentially. The wafer is first tested at normal temperature (approximately 25° C.), then at high temperature (80° C. to 125° C.), and finally at low temperature (−25° C. or below). The pre-DVS data can be acquired from at least one sub-stage. For example, for the normal temperature CP testing sub-stage NTCP, a machine learning model ML1 of the processor 12 receives the pre-DVS data from the normal temperature CP testing sub-stage NTCP. The pre-DVS data acquired from the normal temperature CP testing sub-stage NTCP is referred to as input data D111. A plurality of DVS block voltages and a plurality of DVS time durations are predetermined based on the normal temperature CP testing sub-stage NTCP. The processor 12 can use the machine learning model ML1 for inferring a DVS block voltage as inference data R11 from the plurality of DVS block voltages based on the input data D111, the plurality of DVS block voltages, and the plurality of DVS time durations. The processor 12 can use the machine learning model ML1 for inferring a DVS block voltage as inference data R11. The inference data R11 is transmitted from the machine learning model ML1 to the normal temperature CP testing sub-stage NTCP. As a result, the normal temperature CP testing sub-stage NTCP can use the DVS block voltage to test the wafer for a corresponding DVS time duration at normal temperature (approximately 25° C.).

For the high temperature CP testing sub-stage HTCP in FIG. 9, a machine learning model ML2 of the processor 12 receives the pre-DVS data from the normal temperature CP testing sub-stage NTCP and the high temperature CP testing sub-stage HTCP. The pre-DVS data acquired from the normal temperature CP testing sub-stage NTCP is referred to as input data D112. The pre-DVS data acquired from the high temperature CP testing sub-stage HTCP is referred to as input data D122. A plurality of DVS block voltages and a plurality of DVS time durations are predetermined based on the high temperature CP testing sub-stage HTCP. The processor 12 can use the machine learning model ML2 for inferring a DVS block voltage as inference data R12 from the plurality of DVS block voltages based on the input data D112, the input data D122, the plurality of DVS block voltages, and the plurality of DVS time durations. The inference data R12 is transmitted from the machine learning model ML2 to the high temperature CP testing sub-stage HTCP. As a result, the high temperature CP testing sub-stage HTCP can use the DVS block voltage to test the wafer for a corresponding DVS time duration at high temperature (80° C. to 125° C.).

For the low temperature CP testing sub-stage LTCP in FIG. 9, a machine learning model ML3 of the processor 12 receives the pre-DVS data from the normal temperature CP testing sub-stage NTCP, the high temperature CP testing sub-stage HTCP, and the low temperature CP testing sub-stage LTCP. The pre-DVS data acquired from the normal temperature CP testing sub-stage NTCP is referred to as input data D113. The pre-DVS data acquired from the high temperature CP testing sub-stage HTCP is referred to as input data D123. The pre-DVS data acquired from the low temperature CP testing sub-stage LTCP is referred to as input data D133. A plurality of DVS block voltages and a plurality of DVS time durations are predetermined based on the low temperature CP testing sub-stage LTCP. The processor 12 can use the machine learning model ML3 for inferring a DVS block voltage as inference data R13 from the plurality of DVS block voltages based on the input data D113, the input data D123, the input data D133, the plurality of DVS block voltages, and the plurality of DVS time durations. The inference data R13 is transmitted from the machine learning model ML3 to the low temperature CP testing sub-stage LTCP. As a result, the low temperature CP testing sub-stage LTCP can use the DVS block voltage to test the wafer for a corresponding DVS time duration at low temperature (−25° C. or below).

The dynamic voltage stress condition optimization system 200 applies different DVS block voltages to different CP testing sub-stages for identifying the optimal DVS conditions for each temperature setting. This ensures that the IC is thoroughly tested for potential issues that may arise under specific thermal conditions. By applying a higher DVS block voltage at lower temperatures (LTCP) and a lower voltage at higher temperatures (HTCP), the system can effectively test the ICs, improving the efficiency and accuracy of the DVS testing flow and contributing to a higher-quality product.

In FIG. 10, the pre-DVS data is acquired from the FT stage performed by the FT station STA3 within the wafer testing flow. This FT stage is further divided into three sub-stages: a normal temperature FT sub-stage NTFT, a high temperature FT sub-stage HTFT, and a low temperature FT sub-stage LTFT. The wafer undergoes a wafer thermal cycling FT process as part of the DVS testing flow during the FT stage. The normal temperature FT sub-stage NTFT, the high temperature FT sub-stage HTFT, and the low temperature FT sub-stage LTFT are processed sequentially. The wafer is first tested at normal temperature (approximately 25° C.), then at high temperature (80° C. to 125° C.), and finally at low temperature (−25° C. or below). The pre-DVS data can be acquired from at least one sub-stage.

For example, for the normal temperature FT sub-stage NTFT, a machine learning model ML1 of the processor 12 receives the pre-DVS data from the normal temperature FT sub-stage NTFT. The pre-DVS data acquired from the normal temperature FT sub-stage NTFT is referred to as input data D311. A plurality of DVS block voltages and a plurality of DVS time durations are predetermined based on the normal temperature FT sub-stage NTFT. The processor 12 can use the machine learning model ML1 for inferring a DVS block voltage as inference data R31 from the plurality of DVS block voltages based on the input data D311, the plurality of DVS block voltages, and the plurality of DVS time durations. The inference data R31 is transmitted from the machine learning model ML1 to the normal temperature FT sub-stage NTFT. As a result, the normal temperature FT sub-stage NTFT can use the DVS block voltage to test the wafer for a corresponding DVS time duration at normal temperature (approximately 25° C.).

For the high temperature FT sub-stage HTFT in FIG. 10, a machine learning model ML2 of the processor 12 receives the pre-DVS data from the normal temperature FT sub-stage NTFT and the high temperature FT sub-stage HTFT. The pre-DVS data acquired from the normal temperature FT sub-stage NTFT is referred to as input data D312. The pre-DVS data acquired from the high temperature FT sub-stage HTFT is referred to as input data D322. A plurality of DVS block voltages and a plurality of DVS time durations are predetermined based on the high temperature FT sub-stage HTFT. The processor 12 can use the machine learning model ML2 for inferring a DVS block voltage as inference data R32 from the plurality of DVS block voltages based on the input data D312, the input data D322, the plurality of DVS block voltages, and the plurality of DVS time durations. The inference data R32 is transmitted from the machine learning model ML2 to the high temperature FT sub-stage HTFT. As a result, the high temperature FT sub-stage HTFT can use the DVS block voltage to test the wafer for a corresponding DVS time duration at high temperature (80° C. to 125° C.).

For the low temperature FT sub-stage LTFT in FIG. 10, a machine learning model ML3 of the processor 12 receives the pre-DVS data from the normal temperature FT sub-stage NTFT, the high temperature FT sub-stage HTFT, and the low temperature FT sub-stage LTFT. The pre-DVS data acquired from the normal temperature FT sub-stage NTFT is referred to as input data D313. The pre-DVS data acquired from the high temperature FT sub-stage HTFT is referred to as input data D323. The pre-DVS data acquired from the low temperature FT sub-stage LTFT is referred to as input data D333. A plurality of DVS block voltages and a plurality of DVS time durations are predetermined based on the low temperature FT sub-stage LTFT. The processor 12 can use the machine learning model ML3 for inferring a DVS block voltage as inference data R33 from the plurality of DVS block voltages based on the input data D313, the input data D323, the input data D333, the plurality of DVS block voltages, and the plurality of DVS time durations. The inference data R33 is transmitted from the machine learning model ML3 to the low temperature FT sub-stage LTFT. As a result, the low temperature FT sub-stage LTFT can use the DVS block voltage to test the wafer for a corresponding DVS time duration at low temperature (−25° C. or below).

Further, in an embodiment, the input data (pre-DVS data of the CP stage) D1 can be introduced for enhancing prediction accuracy. In another embodiment, the input data D1 is optional since the machine learning models ML1 to ML3 can still function effectively without it. Any hardware or technology modification falls within the scope of the embodiments.

The dynamic voltage stress condition optimization system 200 applies different DVS block voltages to different FT sub-stages for identifying the optimal DVS conditions for each temperature setting. This ensures that the IC is thoroughly tested for potential issues that may arise under specific thermal conditions. By applying a higher DVS block voltage at lower temperatures (LTFT) and a lower voltage at higher temperatures (HTFT), the system can effectively test the ICs, improving the efficiency and accuracy of the DVS testing flow and contributing to a higher quality product.

In FIG. 11, the pre-DVS data is acquired from the SLT stage performed by the SLT station STA4 within the wafer testing flow. This SLT stage is further divided into three sub-stages: a normal temperature SLT sub-stage NTSLT, a high-temperature SLT sub-stage HTSLT, and a low-temperature SLT sub-stage LTSLT. The wafer undergoes a wafer thermal cycling SLT process as part of the DVS testing flow during the SLT stage. The normal temperature SLT sub-stage NTSLT, the high-temperature SLT sub-stage HTSLT, and the low-temperature SLT sub-stage LTSLT are processed sequentially. The wafer is first tested at the normal temperature (approximately 25° C.), then at the high temperature (80° C. to 125° C.), and finally at the low temperature (−25° C. or below). The pre-DVS data can be acquired from at least one sub-stage. For example, for the normal temperature SLT sub-stage NTSLT, a machine learning model ML1 of the processor 12 receives the pre-DVS data from the normal temperature SLT sub-stage NTSLT. The pre-DVS data acquired from the normal temperature SLT sub-stage NTSLT is referred to as input data D411. A plurality of DVS block voltages and a plurality of DVS time durations are predetermined based on the normal temperature SLT sub-stage NTSLT. The processor 12 can use the machine learning model ML1 for inferring a DVS block voltage as inference data R41 from the plurality of DVS block voltages based on the input data D411, the plurality of DVS block voltages, and the plurality of DVS time durations. The processor 12 can use the machine learning model ML1 for inferring a DVS block voltage as inference data R41. The inference data R41 is transmitted from the machine learning model ML1 to the normal temperature SLT sub-stage NTSLT. As a result, the normal temperature SLT sub-stage NTSLT can use the DVS block voltage to test the wafer for a corresponding DVS time duration at normal temperature (approximately 25° C.).

For the high-temperature SLT sub-stage HTSLT in FIG. 11, a machine learning model ML2 of the processor 12 receives the pre-DVS data from the normal temperature SLT sub-stage NTSLT and the high-temperature SLT sub-stage HTSLT. The pre-DVS data acquired from the normal temperature SLT sub-stage NTSLT is referred to as input data D412. The pre-DVS data acquired from the high-temperature SLT sub-stage HTSLT is referred to as input data D422. A plurality of DVS block voltages and a plurality of DVS time durations are predetermined based on the high-temperature SLT sub-stage HTSLT. The processor 12 can use the machine learning model ML2 for inferring a DVS block voltage as inference data R42 from the plurality of DVS block voltages based on the input data D412, the input data D422, the plurality of DVS block voltages, and the plurality of DVS time durations. The inference data R42 is transmitted from the machine learning model ML2 to the high-temperature SLT sub-stage HTSLT. As a result, the high-temperature SLT sub-stage HTSLT can use the DVS block voltage to test the wafer for a corresponding DVS time duration at high temperature (80° C. to 125° C.).

For the low-temperature SLT sub-stage LTSLT in FIG. 11, a machine learning model ML3 of the processor 12 receives the pre-DVS data from the normal temperature SLT sub-stage NTSLT, the high-temperature SLT sub-stage HTSLT, and the low-temperature SLT sub-stage LTSLT. The pre-DVS data acquired from the normal temperature SLT sub-stage NTSLT is referred to as input data D413. The pre-DVS data acquired from the high-temperature SLT sub-stage HTSLT is referred to as input data D423. The pre-DVS data acquired from the low-temperature SLT sub-stage LTSLT is referred to as input data D433. A plurality of DVS block voltages and a plurality of DVS time durations are predetermined based on the low-temperature SLT sub-stage LTSLT. The processor 12 can use the machine learning model ML3 for inferring a DVS block voltage as inference data R43 from the plurality of DVS block voltages based on the input data D413, the input data D423, the input data D433, the plurality of DVS block voltages, and the plurality of DVS time durations. The inference data R43 is transmitted from the machine learning model ML3 to the low-temperature SLT sub-stage LTSLT. As a result, the low-temperature SLT sub-stage LTSLT can use the DVS block voltage to test the wafer for a corresponding DVS time duration at low temperature (−25° C. or below). Further, in an embodiment, the input data (pre-DVS data of the CP stage) D1 and the input data (pre-DVS data of the FT stage) D3 can be introduced for enhancing the prediction accuracy. In another embodiment, the input data D1 and the input data D3 are optional since the machine learning models ML1 to ML3 can still function effectively without them. Any hardware or technology modification falls within the scope of the embodiments.

The dynamic voltage stress condition optimization system 200 applies different DVS block voltages to different SLT sub-stages for identifying the optimal DVS conditions for each temperature setting. This ensures that the IC is thoroughly tested for potential issues that may arise under specific thermal conditions. By applying a higher DVS block voltage at lower temperatures (LTSLT) and a lower voltage at higher temperatures (HTSLT), the system can effectively test the ICs, improving the efficiency and accuracy of the DVS testing flow and contributing to a higher quality product.

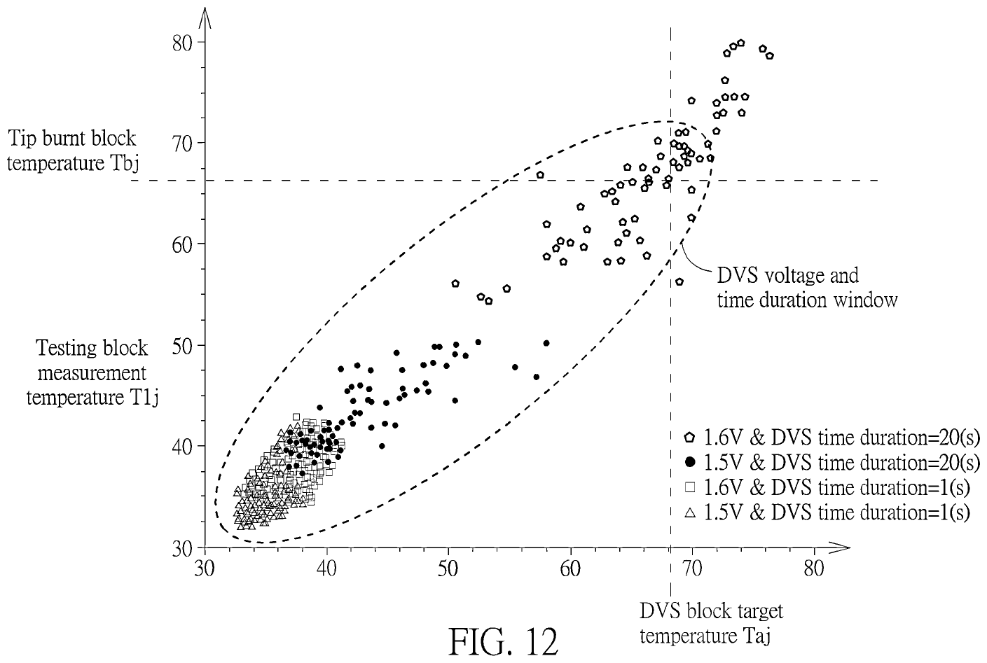

FIG. 12 is an illustration of a correlation table applied to data flow modes in FIG. 9 to FIG. 11 of the dynamic voltage stress condition optimization system 200. In FIG. 12, the Y-axis shows the testing block measurement temperature of the j-th testing block, denoted as a post-DVS temperature T1j. The X-axis shows a DVS block predict temperature of the j-th testing block, denoted as a predicted post-DVS temperature T2j. The tip burnt block temperature of the j-th testing block is denoted as Tbj. The tip burnt block temperature Tbj can be regarded as the maximum tolerance temperature of the j-th testing block under the DVS testing flow. As previously mentioned, to optimize the DVS process for better quality assurance, the dynamic voltage stress condition optimization system 200 can use a machine learning model to predict the post-DVS temperature of the IC. This prediction is based on two main factors: pre-DVS Data and DVS Time Duration. In FIG. 12, the dynamic voltage stress condition optimization system 200 considers four specific DVS conditions. For example, under the condition of “1.6V & DVS time duration=20(s)”, a high voltage (1.6V) is applied for a long duration (20 seconds), resulting in the distribution of both post-DVS and predicted post-DVS temperatures at high-temperature positions. Under the condition of “1.5V & DVS time duration=20(s)”, a moderate voltage (1.5V) is applied for the long duration (20 seconds), resulting in the distribution of both post-DVS and predicted post-DVS temperatures at normal-temperature positions. Under the condition of “1.6V & DVS time duration=1(s)”, a high voltage (1.6V) is applied for a concise duration (1 second), resulting in the distribution of both post-DVS and predicted post-DVS temperatures at normal-temperature positions. Under the condition of “1.5V & DVS time duration=1(s)”, the moderate voltage (1.5V) is applied for a concise duration (1 second), resulting in the distribution of both post-DVS and predicted post-DVS temperatures at low-temperature positions.

Further, the “DVS voltage and time duration window” in FIG. 12 refers to a range of DVS conditions applied to ICs during testing. This window encompasses both the DVS voltage level and the voltage application duration. By varying these parameters within the window, manufacturers can assess device performance and reliability under different stress levels, ensuring its ability to withstand the electrical and thermal challenges encountered during operation. Based on the tip burnt block temperature Tbj and the correlation table, the DVS block target temperature of the j-th testing block can be determined, denoted as Taj. When the DVS block voltage corresponding to the DVS block target temperature Taj is applied to the j-th testing block to perform the DVS testing flow for a DVS time duration (e.g., 20 seconds), the j-th testing block's measured temperature approaches the tip burnt block temperature Tbj. When the processor 12 increases the DVS block voltage or the DVS time duration to approach the testing block measurement temperature to the tip burnt block temperature Tbj, the power of the testing blocks increases, leading to a reduction of defect parts per million (DPPM).

In summary, the present embodiments disclose a dynamic voltage stress condition optimization method and a dynamic voltage stress condition optimization system. This system functions as a block-based DVS block voltage allocation system, generating specific DVS block voltages based on the target temperature for each block. When a testing block undergoes the DVS testing flow, the system ensures that the measured temperature of the block approaches its maximum tolerance temperature (tip burnt block temperature) by adjusting the DVS block voltage or the DVS time duration. Furthermore, the embodiments allow for different DVS block voltages to be applied to different testing blocks. By adaptively applying these voltages to their corresponding blocks, the efficiency and accuracy of the DVS testing flow are significantly improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dynamic voltage stress (DVS) condition optimization method comprising:
selecting a testing block from a plurality of testing blocks in a die of a wafer;
acquiring a plurality of testing block measurement temperatures of the testing block when the testing block is processed by a DVS testing flow;
acquiring a correlation table of the plurality of testing block measurement temperatures and a plurality of DVS block predict temperatures of the testing block;
configuring a tip burnt block temperature based on the plurality of testing block measurement temperatures;
determining a DVS block target temperature selected from the DVS block predict temperatures based on the correlation table and the tip burnt block temperature; and
generating a DVS block voltage for applying to the testing block in the die of the wafer based on the DVS block target temperature.

2. The method of claim 1, further comprising:
adjusting the DVS block voltage for applying to another testing block in the die of the wafer;
wherein the die of the wafer comprises a plurality of testing blocks, and the plurality of testing blocks are applied with different DVS block voltages.

3. The method of claim 1, further comprising:
acquiring pre-DVS data of the wafer before the wafer is processed by the DVS testing flow;
setting a plurality of DVS block voltages and a plurality of DVS time durations; and
generating the plurality of DVS block predict temperatures of the testing block to establish the correlation table by a machine learning architecture based on the pre-DVS data, the plurality of DVS block voltages and the plurality of DVS time durations;
wherein the pre-DVS data comprises at least one testing environment temperature of the die.

4. The method of claim 3, wherein the pre-DVS data is acquired from a chip probe (CP) stage performed by a CP station of a wafer testing flow, the CP stage comprises a normal temperature CP testing sub-stage, a high temperature CP testing sub-stage, and a low temperature CP testing sub-stage, and the wafer is processed by a wafer thermal cycling CP testing process of the DVS testing flow in the CP stage.

5. The method of claim 4, wherein the normal temperature CP testing sub-stage, the high temperature CP testing sub-stage, and the low temperature CP testing sub-stage are processed sequentially, the pre-DVS data is acquired from a group comprising the normal temperature CP testing sub-stage, the high temperature CP testing sub-stage, and the low temperature CP testing sub-stage, and the plurality of DVS block voltages and the plurality of DVS time durations are predetermined based on one sub-stage of the CP normal temperature testing sub-stage, the high temperature CP testing sub-stage, and the low temperature CP testing sub-stage.

6. The method of claim 3, wherein the pre-DVS data is acquired from a final test (FT) stage performed by an FT station of a wafer testing flow, the FT stage comprises a normal temperature FT sub-stage, a high temperature FT sub-stage, and a low temperature FT sub-stage, and the wafer is processed by a wafer thermal cycling FT process of the DVS testing flow in the FT stage.

7. The method of claim 6, wherein the normal temperature FT sub-stage, the high temperature FT sub-stage, and the low temperature FT sub-stage are processed sequentially, the pre-DVS data is acquired from a group comprising the normal temperature FT sub-stage, the high temperature FT sub-stage, and the low temperature FT sub-stage, and the plurality of DVS block voltages and the plurality of DVS time durations are predetermined based on one sub-stage of the FT normal temperature testing sub-stage, the high temperature FT sub-stage, and the low temperature FT sub-stage.

8. The method of claim 3, wherein the pre-DVS data is acquired from a system-level testing (SLT) stage performed by an STL station of a wafer testing flow, the SLT stage comprises a normal temperature SLT sub-stage, a high temperature SLT sub-stage, and a low temperature SLT sub-stage, and the wafer is processed by a wafer thermal cycling SLT process of the DVS testing flow in the SLT stage.

9. The method of claim 8, wherein the normal temperature SLT sub-stage, the high temperature SLT sub-stage, and the low temperature SLT sub-stage are processed sequentially, the pre-DVS data is acquired from a group comprising the normal temperature SLT sub-stage, the high temperature SLT sub-stage, and the low temperature SLT sub-stage, and the plurality of DVS block voltages and the plurality of DVS time durations are predetermined based on one sub-stage of the SLT normal temperature testing sub-stage, the high temperature SLT sub-stage, and the low temperature SLT sub-stage.

10. The method of claim 1, further comprising:
increasing the DVS block voltage or increasing a DVS time duration so as to approach the DVS block target temperature to a tip burnt block temperature;
wherein when the DVS block voltage or the DVS time duration is increased, a power of testing blocks is increased so as to increase the DVS block target temperature.

11. A dynamic voltage stress (DVS) condition optimization system comprising:
at least one wafer testing station;
a memory; and
a processor coupled to the memory and the at least one wafer testing station;
wherein the processor selects a testing block from a plurality of testing blocks in a die of a wafer, the processor acquires a plurality of testing block measurement temperatures of the testing block from the at least one wafer testing station when the testing block is processed by a DVS testing flow, the processor acquires a correlation table of the plurality of testing block measurement temperatures and a plurality of DVS block predict temperatures of the testing block, the correlation table is saved in the memory, the processor configures a tip burnt block temperature based on the testing block measurement temperatures, the processor determines a DVS block target temperature selected from the DVS block predict temperatures based on the correlation table and the tip burnt block temperature, and the processor generates a DVS block voltage for applying to the testing block in the die of the wafer based on the DVS block target temperature.

12. The system of claim 11, wherein the processor adjusts the DVS block voltage for applying to another testing block in the die of the wafer, the die of the wafer comprises a plurality of testing blocks, and the plurality of testing blocks are applied with different DVS block voltages.

13. The system of claim 11, wherein the processor acquires pre-DVS data of the wafer before the wafer is processed by the DVS testing flow, the processor sets a plurality of DVS block voltages and a plurality of DVS time durations, the processor generates the plurality of DVS block predict temperatures of the testing block to establish the correlation table by a machine learning architecture based on the pre-DVS data, the plurality of DVS block voltages and the plurality of DVS time durations, and the pre-DVS data comprises at least one testing environment temperature of the die.

14. The system of claim 13, wherein the pre-DVS data is acquired from a chip probe (CP) stage performed by a CP station of a wafer testing flow, the CP stage comprises a normal temperature CP testing sub-stage, a high temperature CP testing sub-stage, and a low temperature CP testing sub-stage, and the wafer is processed by a wafer thermal cycling CP testing process of the DVS testing flow in the CP stage.

15. The system of claim 14, wherein the normal temperature CP testing sub-stage, the high temperature CP testing sub-stage, and the low temperature CP testing sub-stage are processed sequentially, the pre-DVS data is acquired from a group comprising the normal temperature CP testing sub-stage, the high temperature CP testing sub-stage, and the low temperature CP testing sub-stage, and the plurality of DVS block voltages and the plurality of DVS time durations are predetermined based on one sub-stage of the CP normal temperature testing sub-stage, the high temperature CP testing sub-stage, and the low temperature CP testing sub-stage.

16. The system of claim 13, wherein the pre-DVS data is acquired from a final test (FT) stage performed by an FT station of a wafer testing flow, the FT stage comprises a normal temperature FT sub-stage, a high temperature FT sub-stage, and a low temperature FT sub-stage, and the wafer is processed by a wafer thermal cycling FT process of the DVS testing flow in the FT stage.

17. The system of claim 16, wherein the normal temperature FT sub-stage, the high temperature FT sub-stage, and the low temperature FT sub-stage are processed sequentially, the pre-DVS data is acquired from a group comprising the normal temperature FT sub-stage, the high temperature FT sub-stage, and the low temperature FT sub-stage, and the plurality of DVS block voltages and the plurality of DVS time durations are predetermined based on one sub-stage of the FT normal temperature testing sub-stage, the high temperature FT sub-stage, and the low temperature FT sub-stage.

18. The system of claim 13, wherein the pre-DVS data is acquired from a system-level testing (SLT) stage performed by an STL station of a wafer testing flow, the SLT stage comprises a normal temperature SLT sub-stage, a high temperature SLT sub-stage, and a low temperature SLT sub-stage, and the wafer is processed by a wafer thermal cycling SLT process of the DVS testing flow in the SLT stage.

19. The system of claim 18, wherein the normal temperature SLT sub-stage, the high temperature SLT sub-stage, and the low temperature SLT sub-stage are processed sequentially, the pre-DVS data is acquired from a group comprising the normal temperature SLT sub-stage, the high temperature SLT sub-stage, and the low temperature SLT sub-stage, and the plurality of DVS block voltages and the plurality of DVS time durations are predetermined based on one sub-stage of the SLT normal temperature testing sub-stage, the high temperature SLT sub-stage, and the low temperature SLT sub-stage.

20. The system of claim 11, wherein the processor increases the DVS block voltage or increases a DVS time duration so as to approach the DVS block target temperature to a tip burnt block temperature, and when the DVS block voltage or the DVS time duration is increased, a power of testing blocks is increased.
